(19) United States
(12) Patent Application Publication
(10) Pub. No.: US 2022/0260976 A1
(43) Pub. Date: Aug. 18, 2022

(54) INFORMATION PROCESSING DEVICE, CONTROL METHOD, AND INFORMATION PROVISION SYSTEM

(71) Applicant: MITSUBISHI ELECTRIC CORPORATION, Tokyo (JP)

(72) Inventors: Satoshi SAKURAI, Tokyo (JP); Yoshiyuki KATO, Tokyo (JP); Kei GOMITA, Tokyo (JP); Fengyi JIN, Tokyo (JP)

(73) Assignee: MITSUBISHI ELECTRIC CORPORATION, Tokyo (JP)

(21) Appl. No.: 17/735,209

(22) Filed: May 3, 2022

Related U.S. Application Data
(63) Continuation of application No. PCT/JP2019/045203, filed on Nov. 19, 2019.

(51) Int. Cl. G05B 19/418

(52) U.S. Cl. CPC G05B 19/41865; G05B 19/41845

(57) ABSTRACT

An information processing device includes a first generation unit that generates second layout information indicating a second layout including a first path as a path of conveyance of an object, the second layout information being information generated by changing first layout information indicating a first layout, a calculation unit that calculates a first conveyance distance as a conveyance distance of the object based on the first path, an acquisition unit that acquires a first conveyance amount indicating an amount of conveyance of the object, and a second generation unit that generates a first diagram indicating a relationship between the first conveyance distance and the first conveyance amount.

### CROSS-REFERENCE TO RELATED APPLICATION

This application is a continuation application of International Application No. PCT/JP2019/045203 having an international filing date of Nov. 19, 2019, which is hereby expressly incorporated by reference into the present application.

### BACKGROUND OF THE INVENTION

### 1. Field of the Invention

The present disclosure relates to an information processing device, a control method and an information provision system.

### 2. Description of the Related Art

In designing of a floor layout in a factory, arrangement of machines and working regions is generally designed so as to achieve high productivity. Systematic Layout Planning (SLP) is known as a method for realizing such arrangement. For example, in SLP, the layout is designed by using P-Q analysis and object flow analysis. In such a circumstance, technology regarding the layout design has been proposed (see Patent Reference 1).

Patent Reference 1: Japanese Patent Application Publication No. 2003-44115

Incidentally, the layout includes paths through which objects are conveyed. Further, Distance Intensity (DI) analysis is known as a method for analyzing the layout. In DI analysis, the layout is evaluated by using a diagram based on a conveyance distance on the basis of the paths and a conveyance amount of objects. This diagram is referred to also as a DI analysis diagram.

There is a case where the layout is changed. When the layout has been changed, the user generates the diagram. Thus, the user generates the diagram each time the layout is changed and it increases the load on the user.

### SUMMARY OF THE INVENTION

An object of the present disclosure is to reduce the load on the user.

An information processing device according to an aspect of the present disclosure is provided. The information processing device includes a first generation unit that generates second layout information indicating a second layout including a first path as a path of conveyance of an object, the second layout information being information generated by changing first layout information indicating a first layout, a calculation unit that calculates a first conveyance distance as a conveyance distance of the object based on the first path, an acquisition unit that acquires a first conveyance amount indicating an amount of conveyance of the object, and a second generation unit that generates a first diagram indicating a relationship between the first conveyance distance and the first conveyance amount.

According to the present disclosure, the load on the user can be reduced.

### BRIEF DESCRIPTION OF THE DRAWINGS

The present disclosure will become more fully understood from the detailed description given hereinbelow and the accompanying drawings which are given by way of illustration only, and thus are not limitative of the present disclosure, and wherein:

FIG. 1 is a diagram showing an information provision system in a first embodiment;

FIG. 2 is a functional block diagram showing the configuration of an information processing device in the first embodiment;

FIG. 3 is a diagram showing an example of a layout in the first embodiment;

FIGS. 4(A) and 4(B) are diagrams showing a concrete example of a case where the position of a rectangle is changed in the first embodiment;

FIG. 5 is a diagram showing a concrete example of a process of generating layout information in which a path start position and a path end position are arranged in the first embodiment;

FIG. 6 is a diagram showing a concrete example of a process of generating layout information including a path in the first embodiment;

FIG. 7 is a diagram showing a flowchart of a DI analysis diagram generation process in the first embodiment;

FIG. 8 shows an example of a DI analysis diagram in the first embodiment;

FIG. 9 is a diagram showing an example of a change of the layout in the first embodiment;

FIG. 10 shows an example of a change of the DI analysis diagram in the first embodiment;

FIG. 11 is a functional block diagram showing the configuration of an information processing device in a third embodiment; and

FIG. 12 is a functional block diagram showing the configuration of an information processing device in a fourth embodiment.

### DETAILED DESCRIPTION OF THE INVENTION

Embodiments will be described below with reference to the drawings. The following embodiments are just examples and a variety of modifications are possible within the scope of the present disclosure.

### First Embodiment

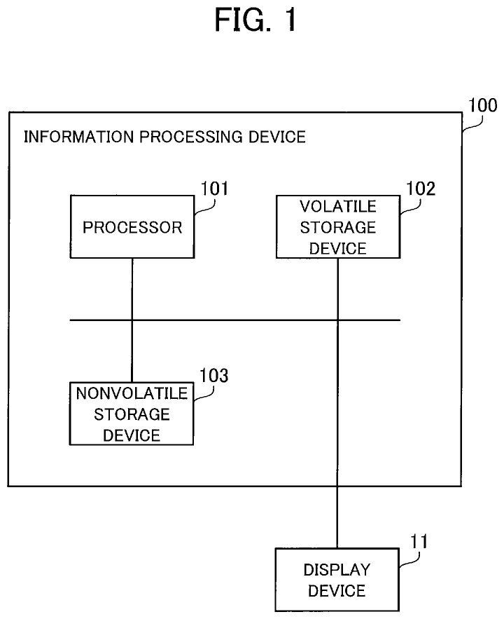

FIG. 1 is a diagram showing an information provision system in a first embodiment. The information provision system includes an information processing device 100 and a display device 11.

The information processing device 100 is a device that executes a control method. Hardware included in the information processing device 100 will be described below.

The information processing device 100 includes a processor 101, a volatile storage device 102 and a nonvolatile storage device 103.

The processor 101 controls the whole of the information processing device 100. For example, the processor 101 is a Central Processing Unit (CPU), a Field Programmable Gate Array (FPGA) or the like. The processor 101 can also be a multiprocessor. The information processing device 100 may also be implemented by a processing circuitry or implemented by software, firmware or a combination of software and firmware. Incidentally, the processing circuitry may be either a single circuit or a combined circuit.

The volatile storage device 102 is main storage of the information processing device 100. The volatile storage device 102 is a Random Access Memory (RAM), for example. The nonvolatile storage device 103 is auxiliary storage of the information processing device 100. The nonvolatile storage device 103 is a Hard Disk Drive (HDD) or a Solid State Drive (SSD), for example.

Next, functions of the information processing device 100 will be described below.

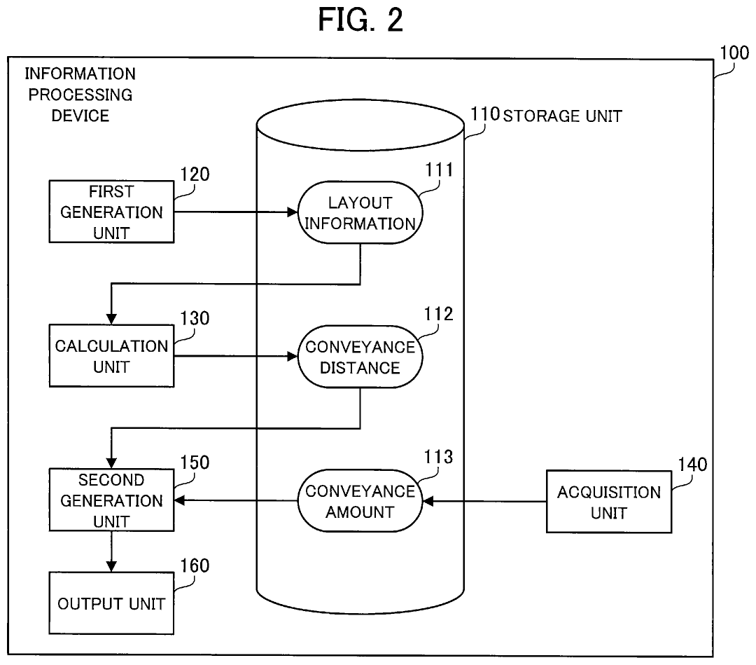

FIG. 2 is a functional block diagram showing the configuration of the information processing device in the first embodiment. The information processing device 100 includes a storage unit 110, a first generation unit 120, a calculation unit 130, an acquisition unit 140, a second generation unit 150 and an output unit 160. Here, the first generation unit 120 may be referred to also as a layout generation unit. The second generation unit 150 may be referred to also as a DI analysis diagram generation unit.

The storage unit 110 may be implemented as a storage area secured in the volatile storage device 102 or the nonvolatile storage device 103.

Part or all of the first generation unit 120, the calculation unit 130, the acquisition unit 140, the second generation unit 150 and the output unit 160 may be implemented by the processor 101.

Part or all of the first generation unit 120, the calculation unit 130, the acquisition unit 140, the second generation unit 150 and the output unit 160 may be implemented as modules of a program executed by the processor 101. For example, the program executed by the processor 101 is referred to also as a control program. The control program has been recorded in a record medium, for example.

The first generation unit 120 generates layout information. Specifically, the first generation unit 120 provides the user with a Graphical User Interface (GUI). Accordingly, the first generation unit 120 generates the layout information, including paths through which objects are conveyed, according to operations by the user. Here, the layout information may also be represented simply as a layout. Further, the object can be work (workpiece), a component, a tool, an article or the like. In the following description, the object can be represented as an article.

Here, the layout information will be described below.

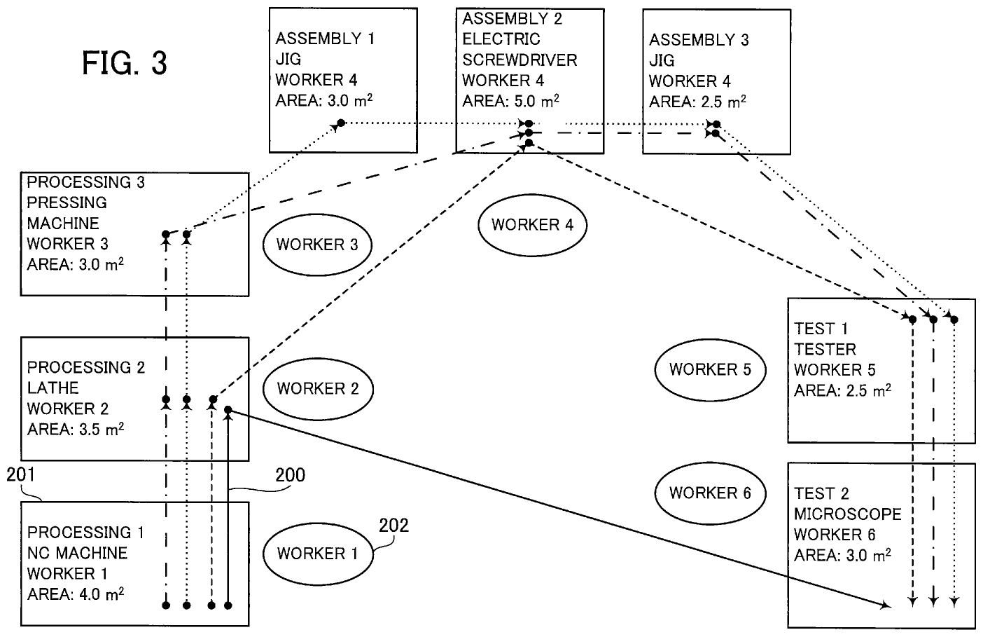

FIG. 3 is a diagram showing an example of the layout in the first embodiment. Specifically, FIG. 3 shows a floor layout in a factory. For example, the first generation unit 120 generates layout information indicated the layout of FIG. 3 according to the user's mouse operation. The layout includes paths through which articles are conveyed. For example, in FIG. 3, a path of conveyance of a certain article is indicated by the arrow 200. A path is indicated by one arrow. In FIG. 3, the shape of each arrow is expressed by using a straight line. However, the shape of each arrow may also be a curved line.

Each region such as a working region, a chair, a wall or a pillar is represented by a rectangle. For example, FIG. 3 shows a region 201 where processing is executed. FIG. 3 shows positions of workers. For example, FIG. 3 shows the position 202 of a worker 1.

Further, the first generation unit 120 is capable of setting a start position and an end position of each path of conveyance of an article according to the user's mouse operation. Here, the start position of a path is referred to as a path start position. The end position of a path is referred to as a path end position. FIG. 3 indicates that a rear end of an arrow is a path start position. Further, FIG. 3 indicates that a front end of an arrow is a path end position. For example, the rear end of the arrow 200 is a path start position. The front end of the arrow 200 is a path end position.

Here, one certain path included in FIG. 3 is referred to also as a second path. Namely, the second path is a path of conveyance of a certain article.

There is a case where the user wants to change the position of a rectangle. A description will be given below of the case where the position of a rectangle is changed.

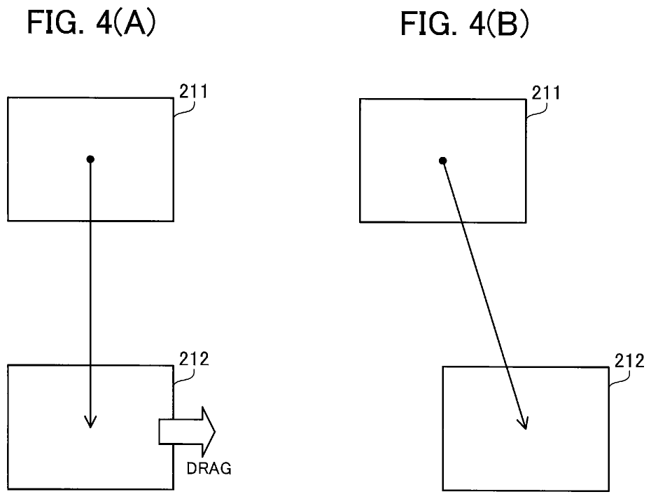

FIGS. 4(A) and 4(B) are diagrams showing a concrete example of the case where the position of a rectangle is changed in the first embodiment. FIG. 4(A) shows a state before changing the position. A rectangle 211 includes a path start position. A rectangle 212 includes a path end position. The user places a pointer on the rectangle 212 by using a mouse. Then, the user performs a drag. Accordingly, the rectangle 212 moves to the right, for example.

When the rectangle 212 has been moved, the first generation unit 120 moves the path end position together with the movement of the rectangle 212. As above, when a rectangular region, with which an end of an arrow indicating a path included in the layout is in contact, has been moved, the first generation unit 120 generates layout information in which the end of the arrow has been moved together with the movement of the rectangular region. Accordingly, the information processing device 100 can maintain the relationship between the rectangle 211 and the rectangle 212 even after the layout is changed.

The first generation unit 120 may generate layout information in which a path start position and a path end position are arranged in the layout so as to minimize the length of a path based on information indicating a plurality of regions. The generation of such layout information will be described below by using a concrete example.

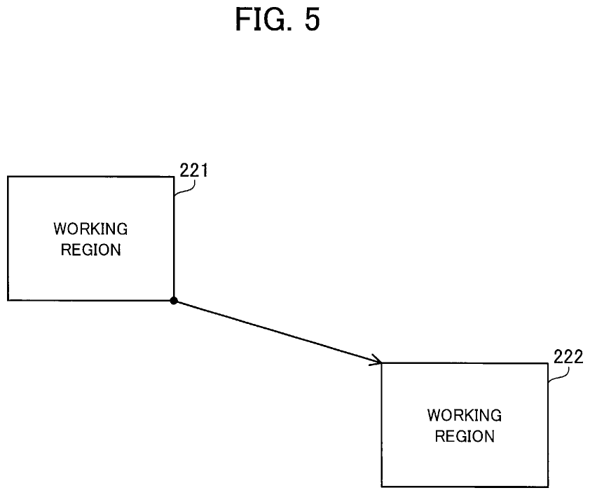

FIG. 5 is a diagram showing a concrete example of a process of generating layout information in which a path start position and a path end position are arranged in the first embodiment. FIG. 5 shows a working region 221 and a working region 222. The first generation unit 120 arranges a path start position on a line segment among four line segments forming the working region 221. The first generation unit 120 arranges a path end position on a line segment among four line segments forming the working region 222. Specifically, the first generation unit 120 identifies combinations between the four line segments forming the working region 221 and the four line segments forming the working region 222. The combinations are 16 combinations. Among the 16 combinations, the first generation unit 120 identifies a combination of line segments that minimizes the distance between line segments. The first generation unit 120 arranges the path start position on one of the two line segments belonging to the identified combination. The first generation unit 120 arranges the path end position on the other line segment.

The first generation unit 120 may generate layout information that includes a path of the shortest length based on information indicating passages, information indicating the path start positions and information indicating the path end positions. The generation of such layout information will be described below by using a concrete example.

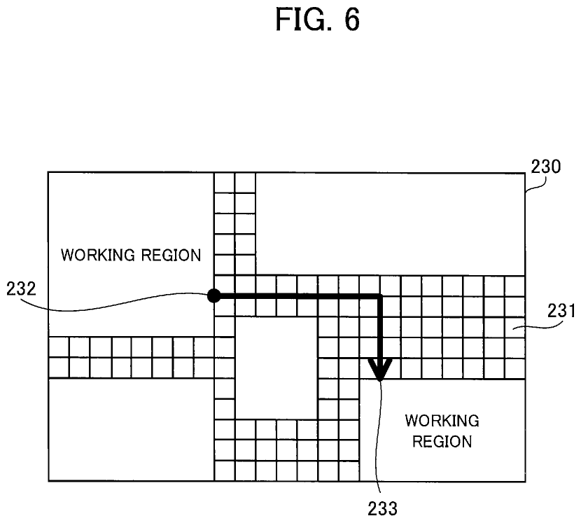

FIG. 6 is a diagram showing a concrete example of a process of generating layout information including a path in the first embodiment. The acquisition unit 140 acquires information 230 indicating passages. For example, the information 230 indicating passages can be an image indicating passages on an actual floor. The passages have been colored with a particular color. The first generation unit 120 is capable of identifying the passages indicated by the particular color by performing image processing. Further, for example, the information 230 indicating passages can also be information generated by Computer-Aided Design (CAD) and indicating the condition of a floor. A label has been assigned to each passage included in the information. The first generation unit 120 identifies each passage based on the label. Any method may be used as the method of identifying each passage. As above, the first generation unit 120 identifies a passage based on the information indicating passages. For example, the first generation unit 120 identifies a passage 231.

FIG. 6 shows a path start position 232. Further, FIG. 6 shows a path end position 233. The first generation unit 120 divides the passage 231 into a plurality of rectangles and calculates the path of the shortest length by using Dijkstra's algorithm. As above, the first generation unit 120 generates layout information including the calculated path.

Incidentally, FIG. 6 shows a case where the shape of the path is not a straight line. Namely, the shape of the arrow is not a straight line. The first generation unit 120 may express the shape of the arrow by using an orthogonal polygonal line.

Further, when a region indicating an obstacle such as a pillar has been set by the user operation, the first generation unit 120 may generate layout information in which the path start position and the path end position has been arranged so as to avoid the region and minimize the length of the path.

The acquisition unit 140 may acquire information for generating the layout information, including labels. For example, the acquisition unit 140 may acquire information generated by CAD and indicating the condition of a floor. The information includes the labels each being capable of identifying a working region, a path, a machine or the like. The first generation unit 120 identifies a working region, a path, a machine or the like based on the labels. The first generation unit 120 generates the layout information based on the identified information. As above, the first generation unit 120 may generate the layout information by using the labels.

The acquisition unit 140 may acquire an image obtained by an image capturing device by photographing a floor. The first generation unit 120 analyzes the image. The first generation unit 120 may generate the layout information based on the result of the analysis.

Further, the layout information may include a tool box, a trash can, a shelf for components, and so forth.

The first generation unit 120 stores the layout information in the storage unit 110. FIG. 2 indicates that layout information 111 has been stored in the storage unit 110.

The calculation unit 130 calculates the conveyance distance based on each path included in the layout information. In the case of the path indicated by the arrow 200, for example, the calculation unit 130 calculates the length of a straight line connecting the path start position as the rear end of the arrow 200 and the path end position as the front end of the arrow 200 as the conveyance distance.

The calculation unit 130 stores the calculated conveyance distances in the storage unit 110. FIG. 2 indicates that information 112 indicating the conveyance distances has been stored in the storage unit 110. Further, when storing a conveyance distance in the storage unit 110, the calculation unit 130 associates reference information, indicating the path corresponding to the conveyance distance, with the conveyance distance.

Here, the conveyance distance calculated based on the second path is referred to also as a second conveyance distance based on the second path.

The acquisition unit 140 acquires the conveyance amount of articles. Specifically, the acquisition unit 140 provides the user with a GUI such as a text box. Accordingly, the acquisition unit 140 acquires the conveyance amount of articles according to the user's input operation. The acquisition unit 140 may also acquire the conveyance amount of articles from an external device connectable to the information processing device 100. Illustration of the external device is omitted in the drawings.

Here, the conveyance amount is the amount of articles conveyed. Specifically, the conveyance amount is the amount of articles conveyed in one path in a predetermined period or a predetermined number of times. Incidentally, this amount is a weight or a quantity. For example, the conveyance amount is the total weight of articles conveyed in one certain path per day. The conveyance amount can also be the total weight of articles conveyed in one certain path per hour, for example. The conveyance amount can also be the total weight of articles conveyed in one certain path each time, for example. The conveyance amount may be changed depending on what is analyzed by the DI analysis.

Here, the acquisition unit 140 acquires the conveyance amount in regard to each path. The acquisition unit 140 stores the acquired conveyance amount in the storage unit 110. Accordingly, the storage unit 110 stores a plurality of conveyance amounts. The plurality of conveyance amounts may also be expressed as follows: The plurality of conveyance amounts respectively indicate the amounts of conveyance through a plurality of paths included in the layout.

FIG. 2 indicates that information 113 indicating the conveyance amounts has been stored in the storage unit 110. Further, when a conveyance amount is stored in the storage unit 110, the acquisition unit 140 associates reference information, indicating the path corresponding to the conveyance amount, with the conveyance amount. As above, the reference information indicating the corresponding path is associated with each of the conveyance amounts.

Next, a process executed by the second generation unit 150 will be described below by using a flowchart.

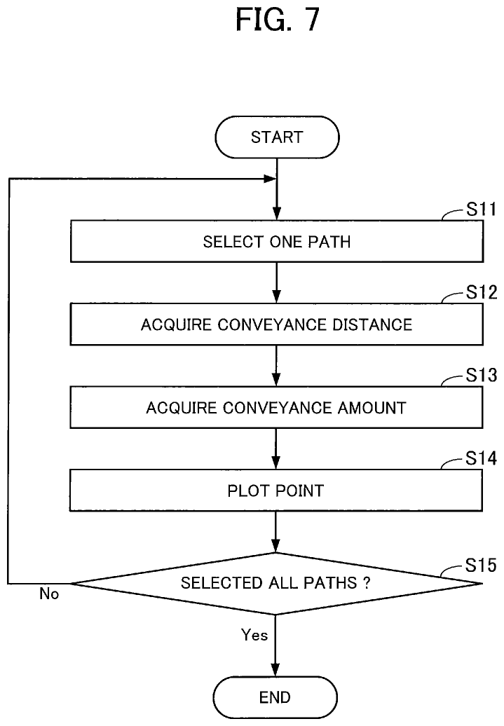

FIG. 7 is a diagram showing a flowchart of a DI analysis diagram generation process in the first embodiment.

(Step S11) The second generation unit 150 selects one path.

(Step S12) The second generation unit 150 acquires the conveyance distance associated with the reference information on the path selected in the step 311 from the storage unit 110.

(Step S13) The second generation unit 150 acquires the conveyance amount associated with the reference information on the path selected in the step S11 from the storage unit 110.

(Step S14) The second generation unit 150 plots a point indicating the relationship between the acquired conveyance distance and conveyance amount on the DI analysis diagram.

(Step S15) The second generation unit 150 judges whether or not all of the paths have been selected. If all of the paths have been selected, the process ends. If there remains a path not selected yet, the second generation unit 150 advances the process to the step S11.

The second generation unit 150 generates the DI analysis diagram as above. For example, when a plurality of paths are included in the layout information, the second generation unit 150 generates a DI analysis diagram including a plurality of points based on the plurality of conveyance distances and the plurality of conveyance amounts respectively corresponding to the plurality of paths.

Next, an example of the DI analysis diagram will be described below.

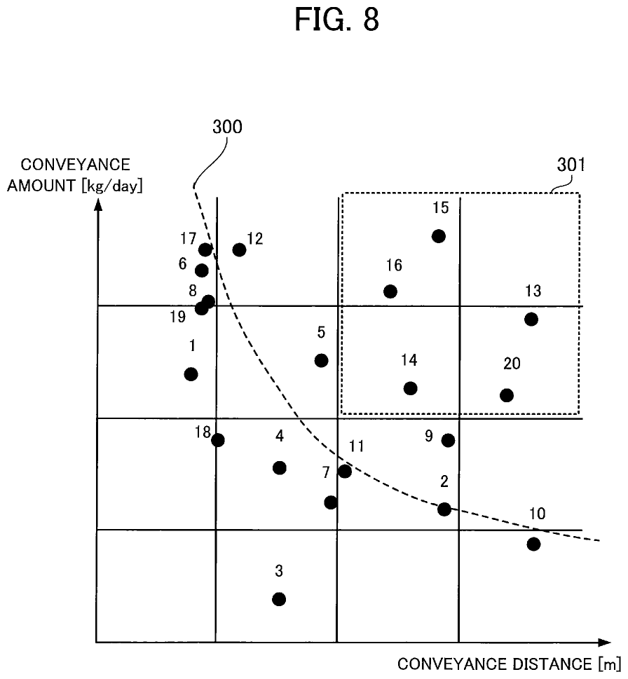

FIG. 8 shows an example of the DI analysis diagram in the first embodiment. The vertical axis represents the conveyance amount. The horizontal axis represents the conveyance distance.

The second generation unit 150 includes an equi-workload line 300 in the DI analysis diagram. The equi-workload line 300 is a line including a plurality of relationship points indicating a plurality of combinations in which a product of multiplication based on the combination of the conveyance distance on the basis of the path and the conveyance amount indicating the amount of conveyance takes on the same value. For example, the product is assumed to be K. The product based on the combination of a certain conveyance distance and a certain conveyance amount is K. The point indicating the relationship between a certain conveyance distance and a certain conveyance amount is referred to as a first relationship point. The product based on the combination of another conveyance distance and another conveyance amount is the same value K. The point indicating the relationship between another conveyance distance and another conveyance amount is referred to as a second relationship point. The first relationship point and the second relationship point are included in the equi-workload line 300.

The product may be determined by the user. The product may be determined based on an average conveyance distance and an average conveyance amount. The equi-workload line 300 is used as a reference for judging whether the position of each plotted point is desirable or not.

As above, the DI analysis diagram includes the plurality of points, respectively indicating the relationship between the plurality of conveyance amounts and the plurality of conveyance distances based on the plurality of paths, and the equi-workload line 300. Here, one point among the plurality of points may be regarded as a first point indicating the relationship between the second conveyance distance and the conveyance amount stored in the storage unit 110. This DI analysis diagram is referred to also as a second diagram.

Further, FIG. 8 indicates a region 301 in which the conveyance distance and the conveyance amount are both great.

The output unit 160 outputs the DI analysis diagram to the display device 11. The display device 11 displays the DI analysis diagram. Accordingly, the user can view the DI analysis diagram. Then, the user can evaluate the layout based on the DI analysis diagram.

For example, the user determines to change the layout since the evaluation of the layout is low. The user executes a layout change operation. A case where the layout information is changed by the layout change operation will be described below.

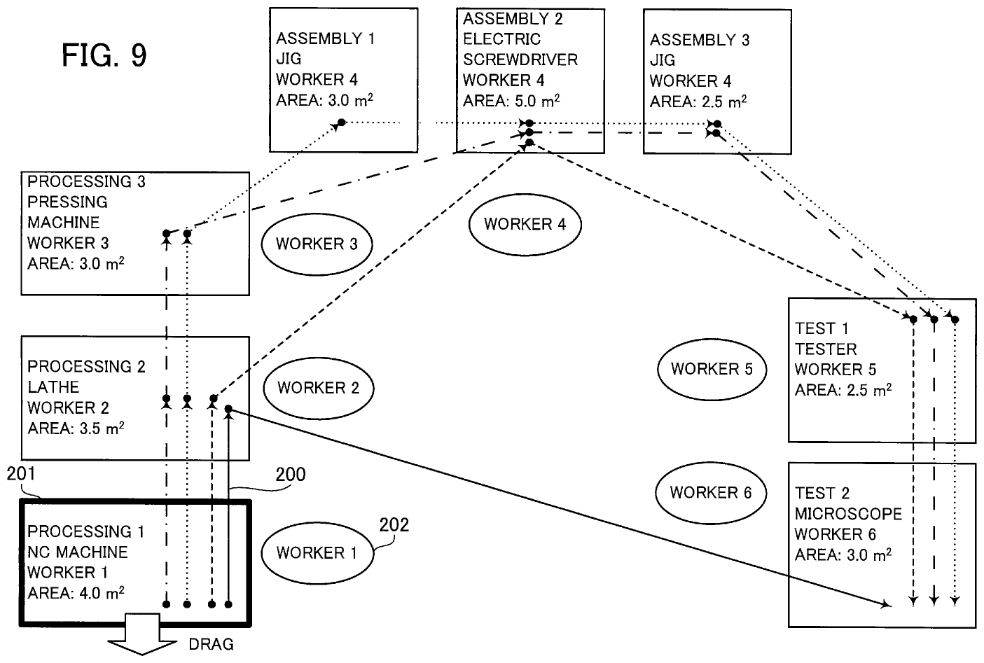

FIG. 9 is a diagram showing an example of the change of the layout in the first embodiment. For example, the user places the pointer in the region 201 by using the mouse. Then, the user performs a drag. Accordingly, the region 201 moves downward, for example.

Here, the layout information before changing the layout is referred to also as first layout information indicating a first layout. For example, the layout shown in FIG. 3 may be regarded as the first layout. Further, the layout information after changing the layout is referred to also as second layout information indicating a second layout. For example, the layout shown in FIG. 9 may be regarded as the second layout.

As above, the first generation unit 120 generates the second layout information by changing the already generated first layout information. Incidentally, the second layout includes a path through which an article is conveyed. This path is referred to also as a first path.

Since the layout has been changed, the lengths of the paths are also changed. Thus, the calculation unit 130 calculates the conveyance distances of articles based on the paths included in the second layout. Here, the conveyance distance may also be represented as the length of the path. When calculating the conveyance distance, the calculation unit 130 may adjust the conveyance distance to suit the actual distance. The conveyance distance calculated by the calculation unit 130 is referred to also as a first conveyance distance.

The acquisition unit 140 acquires the conveyance amount of articles. This process will be described in detail below. When the user changes the conveyance amount accompanying the change of the layout, the acquisition unit 140 acquires the conveyance amount of articles according to the user's input operation. The acquisition unit 140 may also acquire the conveyance amount of articles from an external device. When the user does not change the conveyance amount accompanying the change of the layout, the acquisition unit 140 acquires the conveyance amount of articles from the storage unit 110. Namely, the acquisition unit 140 acquires the conveyance amount of articles already stored in the storage unit 110 before the change of the layout. Incidentally, the conveyance amount acquired by the acquisition unit 140 is referred to also as a first conveyance amount.

The second generation unit 150 generates a diagram indicating the relationship between the conveyance distances calculated by the calculation unit 130 and the conveyance amounts acquired by the acquisition unit 140. Namely, the second generation unit 150 generates a DI analysis diagram indicating the relationship between the conveyance distances and the conveyance amounts. Incidentally, this DI analysis diagram is referred to also as a first diagram. In the process by the second generation unit 150, a DI analysis diagram including the equi-workload line may be generated. Thanks to the equi-workload line included in the DI analysis diagram, the user can judge whether the layout is desirable or not with ease.

The output unit 160 outputs the DI analysis diagram to the display device 11. The display device 11 displays the DI analysis diagram. The output unit 160 may also output the DI analysis diagram to another device. Further, the output unit 160 may also output the DI analysis diagram to a paper medium via a printing device. As above, the output unit 160 can provide the user with the DI analysis diagram after the layout change by outputting the DI analysis diagram to the display device 11.

Next, an example of the DI analysis diagram generated by the second generation unit 150 will be described below.

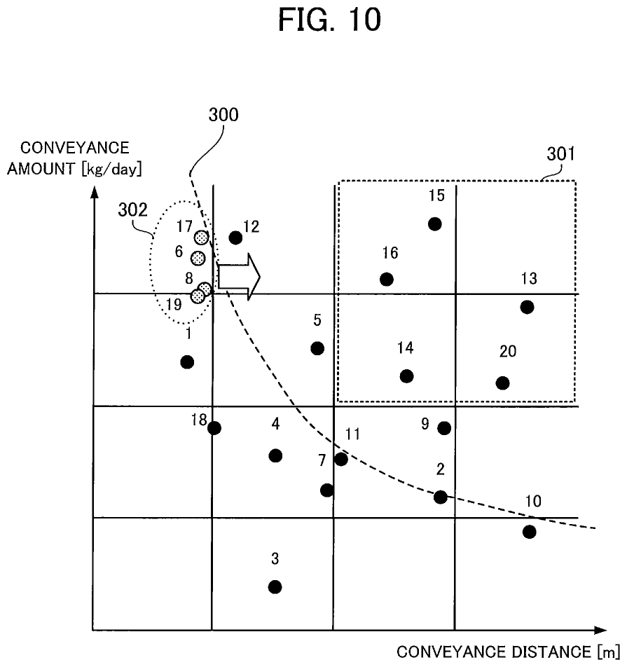

FIG. 10 shows an example of the change of the DI analysis diagram in the first embodiment. FIG. 10 indicates a frame 302. A plurality of points are included in the frame 302. FIG. 10 indicates that the plurality of points are moved rightward due to the layout change. Namely, the second generation unit 150 generates a DI analysis diagram in which the plurality of points have moved rightward.

As above, each time the layout is changed, the user can evaluate the layout by checking the changed DI analysis diagram.

According to the first embodiment, the information processing device 100 generates the DI analysis diagram each time the layout information is changed. This relieves the user of the need to generate the DI analysis diagram. Accordingly, the information processing device 100 is capable of reducing the load on the user.

### Second Embodiment

Next, a second embodiment will be described below. In the second embodiment, the description will be given mainly of features different from those in the first embodiment. In the second embodiment, the description is omitted for features in common with the first embodiment. FIGS. 1 to 10 are referred to in the second embodiment.

The first generation unit 120 may automatically change the layout based on the DI analysis diagram. Specifically, when the second conveyance distance is greater than or equal to a first threshold value, the conveyance amount stored in the storage unit 110 is greater than or equal to a second threshold value and the point indicating the relationship between the second conveyance distance and the conveyance amount is the most separate from the equi-workload line 300 among the plurality of points included in the DI analysis diagram, the first generation unit 120 generates second layout information that includes the first path as a path shorter than the length of the second path. The process executed by the first generation unit 120 will be described concretely below. The first generation unit 120 identifies a point that is the most separate from the equi-workload line 300 in an upper right direction. For example, the first generation unit 120 identifies the point 15 in FIG. 8. The first generation unit 120 judges the point 15 as a point of the lowest evaluation. The first generation unit 120 identifies a working region including the path start position of the path corresponding to the conveyance distance of the point 15 and a working region including the path end position of the path. The first generation unit 120 changes the path so that the length of the path becomes shorter by moving at least one of the working region including the path start position and the working region including the path end position. By repeating this process, the first generation unit 120 is capable of generating a layout including a smaller number of paths whose conveyance distance and conveyance amount are both great.

The first generation unit 120 may automatically change the layout by using any different algorithm. Specifically, the first generation unit 120 calculates an evaluation value based on a plurality of points included in the DI analysis diagram. Here, the evaluation value is a value indicating the evaluation of the first layout. The evaluation value is calculated as follows: For example, the first generation unit 120 calculates a product of multiplication based on the conveyance distance and the conveyance amount in regard to each point in FIG. 8. Accordingly, the first generation unit 120 calculates a plurality of products corresponding to the plurality of points. The first generation unit 120 calculates the sum total of the plurality of products. The first generation unit 120 calculates the evaluation value by using the following expression (1):

evaluation value=1/sum total (1)

The first generation unit 120 changes the layout by solving an evaluation value minimization problem by using an optimization algorithm such as Genetic Algorithm (GA). Namely, the first generation unit 120 changes the first layout information to the second layout information so that the calculated evaluation value becomes a value higher than the original evaluation value. By this method, the information processing device 100 is capable of generating a layout with a high evaluation value.

Further, the first generation unit 120 may express the shape of each path included in the layout information after the change by using any desired shape. For example, the first generation unit 120 expresses each path included in the second layout information by using an orthogonal polygonal line. Here, passages in a factory are often secured in parallel with wall surfaces. Thus, the information processing device 100 can calculate an appropriate conveyance distance by expressing each path by using an orthogonal polygonal line.

Further, when calculating the conveyance distance of a path by using an orthogonal polygonal line, the calculation unit 130 calculates the sum total of the lengths of a plurality of straight lines forming the orthogonal polygonal line as the conveyance distance.

### Third Embodiment

Next, a third embodiment will be described below. In the third embodiment, the description will be given mainly of features different from those in the first embodiment. In the third embodiment, the description is omitted for features in common with the first embodiment. FIGS. 1 to 10 are referred to in the third embodiment.

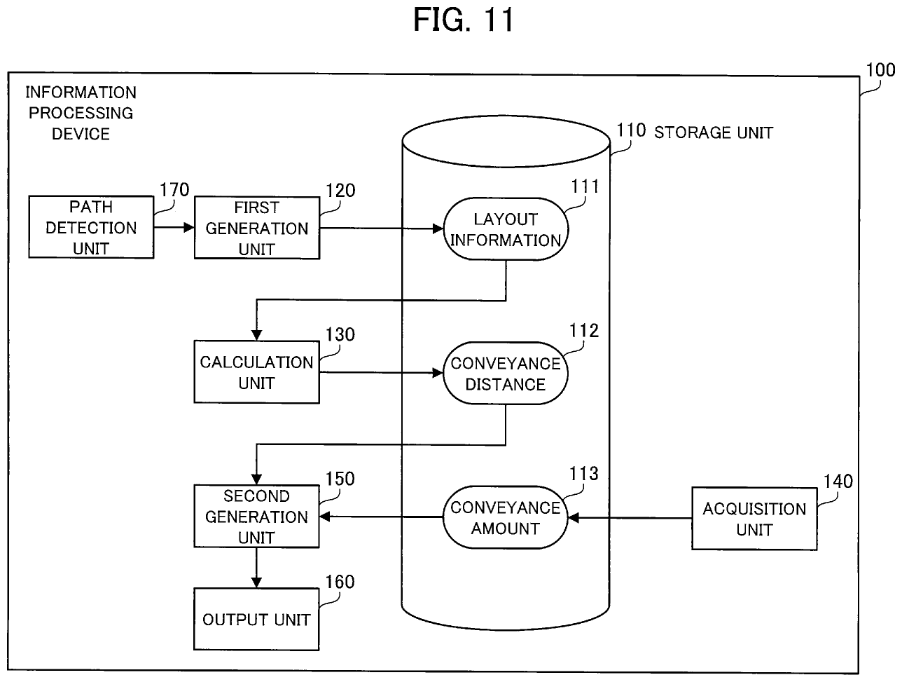

FIG. 11 is a functional block diagram showing the configuration of an information processing device in the third embodiment. The information processing device 100 further includes a path detection unit 170. Each component in FIG. 11 that is the same as a component shown in FIG. 2 is assigned the same reference character as in FIG. 2.

The path detection unit 170 detects a path included in the first layout or a path included in the second layout based on radio waves emitted from a beacon attached to an article. Incidentally, the beacon is referred to also as a transmission device. The path detection unit 170 may also detect a path based on radio waves emitted from a beacon attached to a worker.

The first generation unit 120 generates the second layout information based on the path detected by the path detection unit 170.

According to the third embodiment, the information processing device 100 is capable of detecting a path automatically.

### Fourth Embodiment

Next, a fourth embodiment will be described below. In the fourth embodiment, the description will be given mainly of features different from those in the first embodiment. In the fourth embodiment, the description is omitted for features in common with the first embodiment. FIGS. 1 to 10 are referred to in the fourth embodiment.

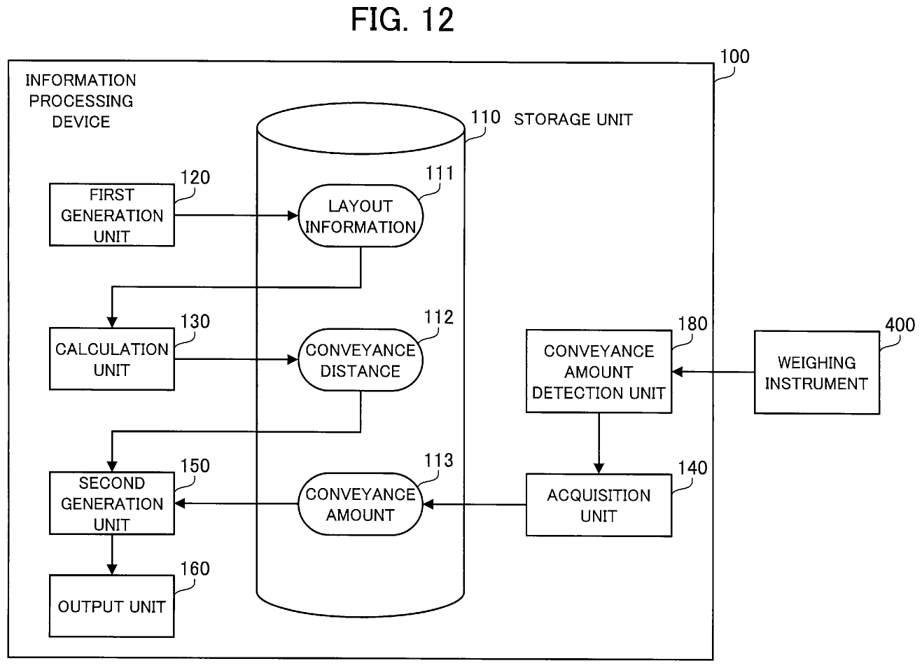

FIG. 12 is a functional block diagram showing the configuration of an information processing device in the fourth embodiment. The information processing device 100 further includes a conveyance amount detection unit 180. Each component in FIG. 12 that is the same as a component shown in FIG. 2 is assigned the same reference character as in FIG. 2.

Here, a weighing instrument 400 is connected to the information processing device 100. For example, the weighing instrument 400 is installed in a working region. Then, the weighing instrument 400 measures the total weight of articles moved by workers to the working region per unit time. The weighing instrument 400 transmits the total weight of articles to the information processing device 100.

The conveyance amount detection unit 180 detects the total weight of articles moved per unit time as the conveyance amount. Alternatively, the conveyance amount detection unit 180 detects the quantity of articles, obtained by dividing the total weight of articles moved per unit time by the weight of one article, as the conveyance amount.

The acquisition unit 140 acquires the conveyance amount from the conveyance amount detection unit 180.

According to the fourth embodiment, the information processing device 100 is capable of acquiring the conveyance amount automatically. Namely, the user is relieved of the need to input the conveyance amount to the information processing device 100. Accordingly, the information processing device 100 is capable of reducing the load on the user.

Features in the embodiments described above can be appropriately combined with each other.

### DESCRIPTION OF REFERENCE CHARACTERS

11: display device, 100: information processing device, 101: processor, 102: volatile storage device, 103: nonvolatile storage device, 110: storage unit, 111: layout information, 112: information, 113: information, 120: first generation unit, 130: calculation unit, 140: acquisition unit, 150: second generation unit, 160: output unit, 170: path detection unit, 180: conveyance amount detection unit, 200: arrow, 201: region, 202: position, 211: rectangle, 212: rectangle, 221, 222: working region, 230: information, 231: passage, 232: path start position, 233: path end position, 300: equi-workload line, 301: region, 302: frame, 400: weighing instrument

What is claimed is:

1. An information processing device comprising:
a first generating circuitry to generate first layout information in which a path start position arranged on a line segment in a region among a plurality of regions and a path end position arranged on a line segment in the other region among the plurality of regions are arranged in a first layout so as to avoid a region indicating an obstacle and minimize the length of a path based on information indicating the region indicating the obstacle and the plurality of regions, the path start position being a start position of a path, the path end position being an end position of the path and generate second layout information indicating a second layout including a first path as a path of conveyance of an object, the second layout information being information generated by changing the first layout information indicating the first layout;
a calculating circuitry to calculate a first conveyance distance as a conveyance distance of the object based on the first path;
an acquiring circuitry to acquire a first conveyance amount indicating an amount of conveyance of the object; and
a second generating circuitry to generate a first diagram indicating a relationship between the first conveyance distance and the first conveyance amount, wherein
the path start position arranged on a line segment in the region and the path end position arranged on a line segment in the other region are arranged at positions where the path avoids the region indicating the obstacle and the length of the path is minimized.

2. The information processing device according to claim 1, wherein the second generating circuitry generates the first diagram that includes an equi-workload line as a line including a plurality of relationship points indicating a plurality of combinations in which a product of multiplication based on the combination of the conveyance distance on the basis of the path and the conveyance amount indicating the amount of conveyance takes on a same value.

3. The information processing device according to claim 1, wherein when a region with which an end of an arrow indicating a path included in the first layout is in contact has been moved, the first generating circuitry generates the second layout information in which the end of the arrow has been moved together with the movement of the region.

4. The information processing device according to claim 1, further comprising a memory to store the first conveyance amount, wherein
the second generating circuitry generates a second diagram that includes a plurality of points an equi-workload line as a line including a plurality of relationship points indicating a plurality of combinations in which a product of multiplication based on the combination of the conveyance distance on the basis of the path and the conveyance amount indicating the amount of conveyance takes on a same value, the plurality of points including a first point indicating a relationship between a second conveyance distance based on a second path as a path of conveyance of the object included in the first layout and the first conveyance amount stored in the memory, and
the first generating circuitry generates the second layout information based on the second diagram.

5. The information processing device according to claim 4, wherein when the second conveyance distance is greater than or equal to a first threshold value, the first conveyance amount is greater than or equal to a second threshold value and the first point is the most separate from the equi-workload line among the plurality of points, the first generating circuitry generates the second layout information indicating the second layout that includes the first path as a path shorter than length of the second path.

6. The information processing device according to claim 1, further comprising a memory to store a plurality of conveyance amounts respectively indicating amounts of conveyance through a plurality of paths included in the first layout, wherein
the second generating circuitry generates a diagram including a plurality of points indicating a relationship between the plurality of conveyance amounts and a plurality of conveyance distances based on the plurality of paths, and
the first generating circuitry changes the first layout information to the second layout information so that an evaluation value as a value indicating evaluation of the first layout based on the plurality of points becomes a value higher than the original evaluation value.

7. The information processing device according to claim 1, wherein the first generating circuitry expresses the first path included in the second layout by using an orthogonal polygonal line.

8. The information processing device according to claim 1, further comprising a path detecting circuitry to detect the first path based on a radio wave emitted from a transmission device attached to the object,
wherein the first generating circuitry generates the second layout information based on the first path detected by the path detecting circuitry.

9. The information processing device according to claim 1, further comprising a conveyance amount detecting circuitry to detect total weight of the objects moved per unit time measured by a weighing instrument as the first conveyance amount,
wherein the acquiring circuitry acquires the first conveyance amount detected by the conveyance amount detecting circuitry.

10. The information processing device according to claim 1, further comprising a conveyance amount detecting circuitry to detect a quantity of the objects, obtained by dividing total weight of the objects moved per unit time measured by a weighing instrument by weight of the object, as the first conveyance amount,
wherein the acquiring circuitry acquires the first conveyance amount detected by the conveyance amount detecting circuitry.

11. The information processing device according to claim 1, further comprising an outputting circuitry to output the first diagram.

12. A control method performed by an information processing device, the control method comprising:
generating first layout information in which a path start position arranged on a line segment in a region among a plurality of regions and a path end position arranged on a line segment in the other region among the plurality of regions are arranged in a first layout so as to avoid a region indicating an obstacle and minimize the length of a path based on information indicating the region indicating the obstacle and the plurality of regions, the path start position being a start position of a path, the path end position being an end position of the path,
generating second layout information indicating a second layout including a first path as a path of conveyance of an object, the second layout information being information generated by changing the first layout information indicating the first layout,
calculating a first conveyance distance as a conveyance distance of the object based on the first path,
acquiring a first conveyance amount indicating an amount of conveyance of the object, and
generating a first diagram indicating a relationship between the first conveyance distance and the first conveyance amount, wherein
the path start position arranged on a line segment in the region and the path end position arranged on a line segment in the other region are arranged at positions where the path avoids the region indicating the obstacle and the length of the path is minimized.

13. An information processing device comprising:
a processor to execute a program; and
a memory to store the program which, when executed by the processor, performs processes of,
generating first layout information in which a path start position arranged on a line segment in a region among a plurality of regions and a path end position arranged on a line segment in the other region among the plurality of regions are arranged in a first layout so as to avoid a region indicating an obstacle and minimize the length of a path based on information indicating the region indicating the obstacle and the plurality of regions, the path start position being a start position of a path, the path end position being an end position of the path,
generating second layout information indicating a second layout including a first path as a path of conveyance of an object, the second layout information being information generated by changing the first layout information indicating the first layout,
calculating a first conveyance distance as a conveyance distance of the object based on the first path,
acquiring a first conveyance amount indicating an amount of conveyance of the object, and
generating a first diagram indicating a relationship between the first conveyance distance and the first conveyance amount, wherein
the path start position arranged on a line segment in the region and the path end position arranged on a line segment in the other region are arranged at positions where the path avoids the region indicating the obstacle and the length of the path is minimized.

14. An information provision system comprising:
an information processing device; and
a display device, wherein
the information processing device includes:
a first generating circuitry to generate first layout information in which a path start position arranged on a line segment in a region among a plurality of regions and a path end position arranged on a line segment in the other region among the plurality of regions are arranged in a first layout so as to avoid a region indicating an obstacle and minimize the length of a path based on information indicating the region indicating the obstacle and the plurality of regions, the path start position being a start position of a path, the path end position being an end position of the path and generate second layout information indicating a second layout including a first path as a path of conveyance of an object, the second layout information being information generated by changing the first layout information indicating the first layout;
a calculating circuitry to calculate a first conveyance distance as a conveyance distance of the object based on the first path;
an acquiring circuitry to acquire a first conveyance amount indicating an amount of conveyance of the object; and
a second generating circuitry to generate a first diagram indicating a relationship between the first conveyance distance and the first conveyance amount, and
the display device displays the first diagram, wherein
the path start position arranged on a line segment in the region and the path end position arranged on a line segment in the other region are arranged at positions where the path avoids the region indicating the obstacle and the length of the path is minimized.
